(19) United States
(12) Patent Application Publication
(10) Pub. No.: US 2004/0185608 A1
(43) Pub. Date: Sep. 23, 2004

(54) Methods of forming integrated circuit devices using buffer layers covering conductive/insulating interfaces

(76) Inventors: Myoung-hwan Oh, Gyeonggi-do (KR); Chang-bong Oh, Gyeonggi-do (KR); Young-wug Kim, Seoul (KR); Hee-sung Kang, Seoul (KR); Hyuk-ju Ryu, Seoul (KR); Young-gun Ko, Gyeonggi-do (KR)

Correspondence Address: MYERS BIGEL SIBLEY & SAJOVEC, PO BOX 37428, RALEIGH, NC, 27627, US

(21) Appl. No.: 10/747,495

(22) Filed: Dec. 29, 2003

(30) Foreign Application Priority Data
Dec. 30, 2002 (KR) 2002-87238

(51) Int. Cl. H01L 21/336

(52) U.S. Cl. 438/197

(57) ABSTRACT

An integrated circuit device is formed by forming a gate conductive layer on a gate insulating layer on a substrate. The gate conductive layer and the gate insulating layer are dry-etched to provide a gate structure. A buffer layer is formed on the sidewall of the gate structure covering an interface in the gate structure between the gate conductive layer and the gate insulating layer. The gate structure is annealed, through the buffer layer, to repair damage caused during the dry-etching.

This application claims the priority of Korean Patent Application No. 2002-87238, filed on Dec. 30, 2002, in the Korean Intellectual Property Office, the disclosure of which is incorporated herein by reference in its entirety.

### FIELD OF THE INVENTION

The invention generally relates to methods of fabricating semiconductor devices and, more particularly, to methods of forming semiconductor devices using gate patterns and devices so formed.

### BACKGROUND

As the density of integrated circuit devices (e.g., semiconductor devices) increases, the size of individual integrated circuits therein may decrease. In particular, highly integrated circuit devices may be realized by decreasing the gate length and the thickness of a gate insulating layer of transistors therein. Decreasing the thickness of gate insulating layers (including SiO₂) may increase the leakage current associated with such transistors. To compensate, the gate insulating layer can be formed of a high K-dielectric material to provide the desired capacitance and to reduce the leakage current.

It is also known to used Hf-series gate insulating layers in small scale transistors. However, during gate reoxidation, oxygen may be diffused into the Hf-series gate insulating layer in a region ranging from the edges of the gate insulating layer to the center thereof. The oxygen can increase the effective thickness of the gate insulating layer, thereby degrading the performance of the transistor.

FIG. 1 is a cross-sectional view showing a thickness of a gate insulating layer after a conventional gate reoxidation process. Referring to FIG. 1, a gate insulating layer 12 (of HfO₂) and a gate conductive layer 14 (of polysilicon) are sequentially deposited on a silicon substrate 10. Afterwards, a gate pattern is formed on the resultant structure by a known photolithographic process.

The gate pattern is typically formed using a dry etch process, which can damage the sidewalls of the gate pattern and the exposed substrate 10. Gate reoxidation is performed to reduce the damage caused by the dry etching process, thereby resulting in a first reoxidation layer 16 being formed on the surface of the exposed gate pattern and the substrate 10. The reoxidation process can cause oxygen to be diffused into an interface between the exposed gate insulating layer 12 and the exposed gate conductive layer 14. Thus, the oxidation can occur in a region ranging from the edges of the gate conductive layer 14 to the center thereof. As shown in a portion “A” of FIG. 1, the first reoxidation layer 16 is formed in the shape of a bird's beak at a region ranging from the edges of the gate pattern to the center thereof. The bird's beak can increase the effective thickness of the gate insulating layer (i.e., the thickness of the gate insulating layer 12 and the thickness of the first reoxidation layer 16), thereby degrading the performance of the transistor.

Further, as the thickness of the gate insulating layer is reduced and the gate length are reduced, the effective thickness of the gate insulating layer can relatively increase, thereby further degrading the performance of the transistor. Gate reoxidation processes are discussed, for example, in U.S. Pat. No. 6,255,206.

### SUMMARY

Embodiments according to the invention can provide methods of forming integrated circuit devices using buffer layers coveing conductive/insulating interfaces. Pursuant to the these embodiments, an integrated circuit device is formed by forming a gate conductive layer on a gate insulating layer on a substrate. The gate conductive layer and the gate insulating layer are dry-etched to provide a gate structure. A buffer layer is formed on the sidewall of the gate structure covering an interface in the gate structure between the gate conductive layer and the gate insulating layer. The gate structure is annealed to repair damage caused during the dry-etching.

In some embodiments according to the invention, the dry-etching the gate conductive layer and the gate insulating layer are dry-etched so that a sidewall of the gate insulating layer is recessed to beneath the gate conductive layer. In some embodiments according to the invention, the buffer layer is formed on the sidewall of the gate insulating layer beneath the gate conductive layer.

In some embodiments according to the invention, forming the buffer layer further includes forming the buffer layer on the interface and on the substrate adjacent to the gate structure and etching to remove at least a portion of the buffer layer from the substrate and to leave at least a portion of the buffer layer on the interface.

In some embodiments according to the invention, etching is performed to remove all of the buffer layer from the substrate adjacent to the interface. In some embodiments according to the invention, first and second buffer layers are formed on the gate structure and on the substrate adjacent to the interface. In some embodiments according to the invention, forming the buffer layer further includes forming a first buffer layer on the gate structure and on the substrate adjacent to the interface and forming a second buffer layer on a sidewall of the gate conductive layer and on the first buffer layer and absent from the substrate adjacent to the interface.

In some embodiments according to the invention, the first buffer layer includes a silicon oxide layer and the second buffer layer includes a silicon nitride layer. In some embodiments according to the invention, the gate insulating layer is formed of at least one of the following insulating materials: silicon oxide, silicon oxynitride, silicon nitride, metal oxide, and metal silicate.

In some embodiments according to the invention, the gate insulating layer is formed of an insulating material having a dielectric constant of at least about 3.9. In some embodiments according to the invention, the gate pattern is formed of polysilicon. In some embodiments according to the invention, the buffer layer is formed of at least one of silicon oxide, silicon nitride, and silicon oxynitride. In some embodiments according to the invention, the buffer layer is formed to a thickness in a range between about 1 Å and about 2000 Å.

In some embodiments according to the invention, the buffer layer is formed only on sidewalls of the gate pattern in the shape of spacers. In some embodiments according to the invention, impurity ions into the substrate using the gate pattern as an ion implantation mask.

In some embodiments according to the invention, the annealing includes O₂-annealing the substrate where the gate pattern is formed. In some embodiments according to the invention, the annealing includes reoxidizing the substrate where the gate patterned is formed.

### BRIEF DESCRIPTION OF THE DRAWINGS

FIG. 1 is a cross-sectional view showing a thickness change of a gate insulating layer after conventional gate reoxidation.

FIGS. 2 through 9 are cross-sectional views illustrating integrated circuit devices and methods of forming the same according to some embodiments of the invention.

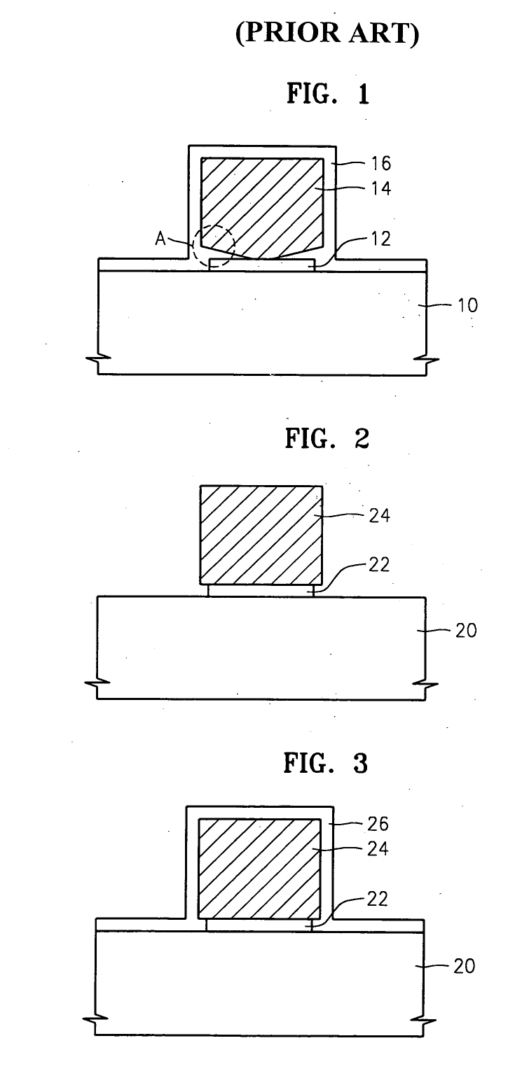

### DESCRIPTION OF EMBODIMENTS ACCORDING TO THE INVENTION

The invention is described herein with reference to the accompanying drawings, in which exemplary embodiments of the invention are shown. In the figures, certain features, layers or components may be exaggerated for clarity. Also, in the figures, broken lines can indicate optional features or components unless stated otherwise. When a layer is referred to as being “on” another layer or substrate, it can be directly on the other layer or substrate, or intervening layers, films, coatings and the like may also be present unless the word “directly” is used which indicates that the feature or layer directly contacts the feature or layer.

Spatially relative terms, such as “beneath”, “below”, “lower”, “above”, “upper”, “bottom”, “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Well-known functions or constructions may not be described in detail for brevity and/or clarity.

FIGS. 2 through 5 are cross-sectional views illustrating integrated circuit devices and methods of forming the same according to some embodiments of the invention. Referring to FIG. 2, a gate insulating layer 22 is deposited using, for example, hafnium oxide (HfO₂), on a single crystalline silicon substrate 20. In some embodiments according to the invention, other types of materials may be used as the substrate 20. A gate conductive layer 24 is deposited using, for example, polysilicon, on the gate insulating layer 22.

A photoresist pattern (not shown) is formed on the gate insulating layer 22 and the gate conductive layer 24. A dry etch is performed (using the photoresist pattern as an etch mask) to form the gate pattern shown in FIG. 2. The sidewalls of the gate pattern (including the sidewalls of the gate insulating layer 22) and the surface of the substrate 20 are exposed to the plasma during at least a portion of the dry etch process, thereby damaging the gate insulating layer 22. In some embodiments according to the invention, the gate insulating layer 22 is formed of an insulating material having a dielectric constant (K) of at least about 3.9.

Although in some embodiments according to the invention, the gate insulating layer 22 is formed of hafnium oxide, other materials can be used for the gate insulating layer 22. For example, the gate insulating layer 22 can be formed using any of the following insulating materials: silicon oxide (SiO₂), silicon oxynitride (SiON), silicon nitride (SiN), metal oxide, and metal silicate as a single layer or multiple layers or combinations thereof.

Although in some embodiments according to the invention the gate conductive layer 24 is formed of polysilicon, other materials can be used. For example, the gate conductive layer 24 can be formed of a variety of conductive layers including a polysilicon layer. In some embodiments according to the invention, a polysilicon layer is formed on the gate insulating layer 22, and an insulating mask layer (not shown) is formed as an uppermost layer constituting the gate conductive layer 24.

In some embodiments according to the invention, the gate insulating layer 22 is etched to completely remove from the gate insulating layer 22 from a surface of the substrate 20 adjacent to the gate pattern. In some embodiments according to the invention, a portion of the gate insulating layer 22 remains on the surface after the dry etch so as not to expose the surface of the substrate 20 adjacent to the gate pattern.

Referring to FIG. 3, a first buffer layer 26 is deposited on the entire surface of the substrate 20 where the gate pattern is formed, for example, of silicon oxide (SiO₂). The first buffer layer 26 can be formed to a thickness sufficient to prevent diffusion of oxygen into an interface between the gate insulating layer 22 and the gate conductive layer 24. For example, in some embodiments according to the invention, the first buffer layer 26 is formed to a thickness in a range between about 1.0 Å and about 2000 Å. In some embodiments according to the invention, the first buffer layer 26 is formed of silicon nitride or silicon oxynitride. In some embodiments according to the invention, the first buffer layer 26 is formed of one of silicon oxide, silicon nitride, and silicon oxynitride, or any combination thereof.

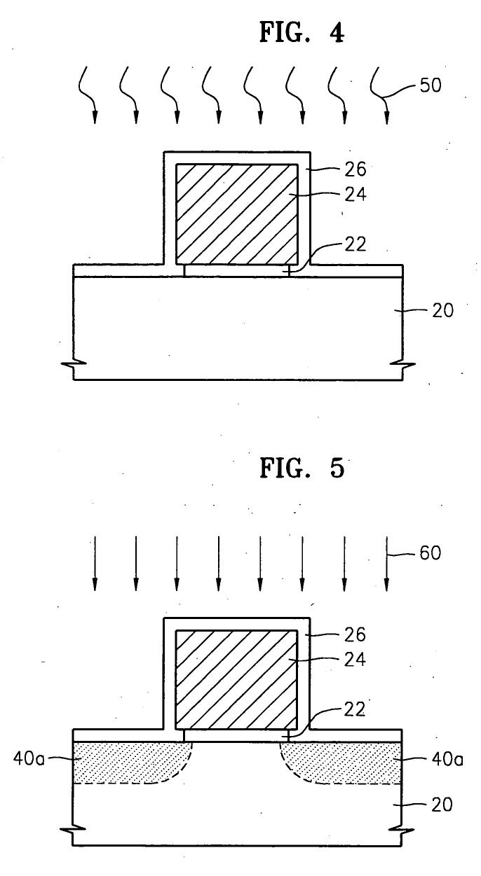

Referring to FIG. 4, an annealing process is performed at a predetermined temperature by applying heat 50 in an oxygen atmosphere to the substrate 20, over the entire surface on which the first buffer layer 26 is formed. The O₂-annealing process is performed to cure damage to the sidewalls of the gate pattern and the surface of the substrate 20 during the etching disclosed above. As shown in FIG. 4, the first buffer layer 26 buffers the sidewalls of the gate insulating layer 22 and the gate conductive layer 24. Thus, lateral diffusion of oxygen can be reduced so as to avoid the formation of a bird's beak at the interface between the gate insulating layer 22 and the gate conductive layer 24 in a region ranging from edges of the gate insulating layer 22 to the center thereof. Accordingly, the thickness of the gate insulating layer 22 can be more uniform across a cross-section thereof. Furthermore, the effective thickness of the gate insulating layer 22 may be reduced.

It will be understood that the annealing process can heat the gate insulating layer 22 and the gate conductive layer 24 through the buffer layer 26 to repair damage that may be caused by the dry-etching. For example, even though FIG. 3 does not show damage to the sidewall of the gate structure, the annealing in FIG. 4 can repair damage to the sidewall by heating through the buffer layer 26 to complete repairs to the damage caused by the dry-etching.

Referring to FIG. 5, impurity ions 60 are implanted into the substrate 20, over the entire surface on which the first buffer layer 26 is deposited, and an annealing process is performed, thereby forming impurity regions 40a, which correspond to source/drain regions of the transistor.

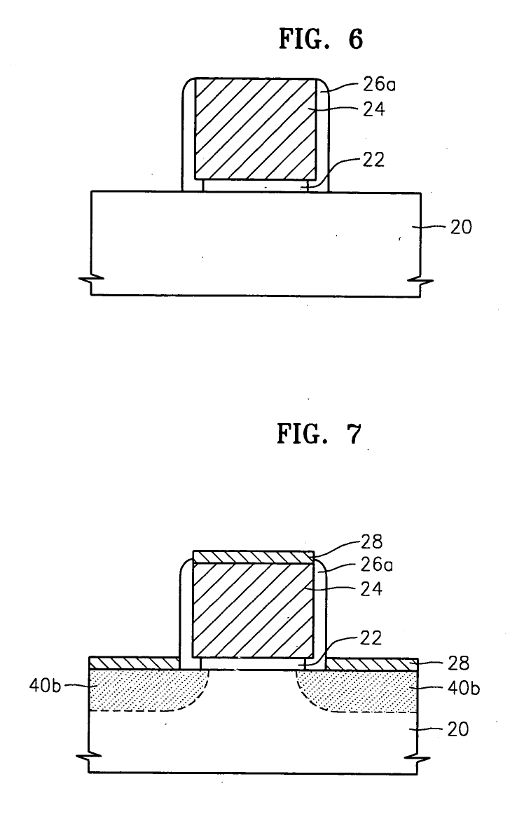

FIGS. 6 and 7 are cross-sectional views illustrating integrated circuit devices and methods of forming the same according to some embodiments of the invention. Referring to FIG. 6, the gate insulating layer 22 and the first buffer layer 26 are formed as disclosed above in reference to FIG. 3. First buffer spacers 26a are formed on the sidewalls of the gate pattern by etching the first buffer layer 26 using an isotropic etch process. The surface of the substrate 20 and the top surface of the gate conductive layer 24 adjacent to the gate pattern are exposed.

Referring to FIG. 7, a typical reoxidation process is performed in an oxygen atmosphere at a temperature of several hundred degrees centigrade to form a second reoxidation layer 28 on the exposed surface of the substrate 20 and the exposed surface of the gate conductive layer 24. The first buffer spacers 26a buffer the sidewalls of the gate insulating layer 22 and the gate conductive layer 24 to reduce the lateral diffusion of oxygen so as to avoid formation of a bird's beak at the interface in a region ranging from the edges of the gate insulating layer 22 to the center thereof. Accordingly, the entire gate insulating layer 22 s can have a more uniform thickness across a cross-section thereof beneath the gate pattern. Furthermore, the effective thickness of the gate insulating layer 22 may not increase.

Impurity ions are implanted into the substrate 20, thereby forming impurity regions 40b, which correspond to source/drain regions of the transistor.

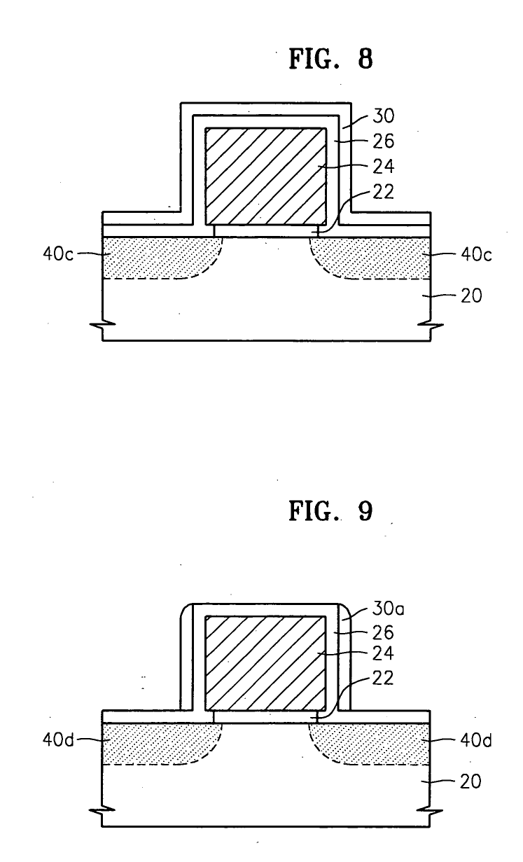

FIG. 8 is a cross-sectional view illustrating integrated circuit devices and methods of forming the same according to embodiments of the invention. Referring to FIG. 8, the gate insulating layer 22 and the first buffer layer 26 can be formed as disclosed above in reference to FIG. 3. A second buffer layer 30 is deposited on the entire surface of the substrate 20 on which the first buffer layer 26 is formed. If the first buffer layer 26 is formed of silicon oxide, the second buffer layer 30 may be formed of silicon nitride. A gate reoxidation process is performed to repair damage caused during the etching used to form the gate pattern. The first buffer layer 26 and the second buffer layer 30 buffer the sidewalls of the gate insulating layer 22 and the gate conductive layer 24 to reduce the lateral diffusion of oxygen so as to avoid formation of a bird's beak at the interface in a region ranging from the edges of the gate insulating layer 22 to the center thereof. Impurity ions are implanted into the substrate 20, thereby forming impurity regions 40c, self-aligned to the gate pattern.

FIG. 9 is a cross-sectional view illustrating integrated circuit devices and methods of forming the same according to some embodiments of the invention. Referring to FIG. 9, the gate insulating layer 22 and the first buffer layer 26 can be formed as disclosed above in reference to FIG. 3.

Second buffer spacers 30a are formed only on the sidewalls of the gate pattern by etching the second buffer layer 30 using an isotropic etch process. A gate reoxidation process is performed to repair damage caused during the etching to form the gate pattern. The first buffer layer 26 and the second buffer spacers 30a buffer the sidewalls of the gate pattern so as to prevent a bird's beak from occurring at the edges of the gate insulating layer 22 (at an interface between the gate insulating layer 22 and the gate conductive layer 24). Impurity ions are implanted into the substrate 20, thereby forming impurity regions 40d, which are self-aligned to the gate pattern.

According to the present invention, a buffer layer is formed on the sidewalls of a gate pattern including a gate insulating layer and a gate conductive layer. A curing process, such as O₂-annealing or reoxidation, is carried out. The curing may impede the diffusion of oxygen into an interface between the gate insulating layer and the gate conductive layer, thereby preventing a bird's beak from occurring at the edges of the gate insulating layer. As a result, damage caused during etching for forming the gate pattern can be sufficiently repaired without substantially increasing the effective thickness of the gate insulating layer.

While the present invention has been particularly shown and described with reference to preferred embodiments thereof, it will be understood by those of ordinary skill in the art that various changes in form and details may be made therein without departing from the spirit and scope of the present invention as defined by the following claims.

What is claimed:

1. A method of forming an integrated circuit device comprising:
forming a gate conductive layer on a gate insulating layer on a substrate;
dry-etching the gate conductive layer and the gate insulating layer gate to provide a gate structure;
forming a buffer layer on the sidewall of the gate structure covering an interface in the gate structure between the gate conductive layer and the gate insulating layer; and
annealing the gate structure through the buffer layer to repair damage caused during the dry-etching.

2. A method according to claim 1 wherein the dry-etching comprises dry-etching the gate conductive layer and the gate insulating layer so that a sidewall of the gate insulating layer is recessed to beneath the gate conductive layer.

3. A method according to claim 2 wherein the forming a buffer layer comprises forming the buffer layer on the sidewall of the gate insulating layer beneath the gate conductive layer.

4. A method according to claim 1 wherein forming a buffer layer further comprises:
forming the buffer layer on the interface and on the substrate adjacent to the gate structure; and
etching to remove at least a portion of the buffer layer from the substrate and to leave at least a portion of the buffer layer on the interface.

5. A method according to claim 4 wherein etching comprises etching to remove all of the buffer layer from the substrate adjacent to the interface.

6. A method according to claim 1 wherein forming the buffer layer comprises forming first and second buffer layers on the gate structure and on the substrate adjacent to the interface.

7. A method according to claim 1 wherein forming the buffer layer comprises:
forming a first buffer layer on the gate structure and on the substrate adjacent to the interface; and
forming a second buffer layer on a sidewall of the gate conductive layer and on the first buffer layer and absent from the substrate adjacent to the interface.

8. A method according to claim 7 wherein the first buffer layer comprises a silicon oxide layer, and the second buffer layer comprises a silicon nitride layer.

9. A method according to claim 1 wherein the gate insulating layer includes at least one of silicon oxide, silicon oxynitride, silicon nitride, metal oxide, and metal silicate.

10. A method according to claim 1 wherein the gate insulating layer comprises an insulating material having a dielectric constant of at least about 3.9.

11. A method according to claim 1 wherein the gate pattern comprises polysilicon.

12. A method according to claim 1 wherein the buffer layer includes at least one of silicon oxide, silicon nitride, and silicon oxynitride.

13. A method according to claim 1 wherein forming the buffer layer comprises forming the buffer layer to a thickness in a range between about 1 Å and about 2000 Å.

14. A method according to claim 1 wherein the buffer layer is formed only on sidewalls of the gate pattern in the shape of spacers.

15. A method according to claim 1 further comprising:
impurity ions into the substrate using the gate pattern as an ion implantation mask.

16. A method according to claim 1 wherein annealing comprises O₂-annealing the substrate where the gate pattern is formed.

17. A method according to claim 1 wherein annealing comprises reoxidizing the substrate where the gate patterned is formed.

18. A method of forming an integrated circuit device comprising:
forming a gate conductive layer on a gate insulating layer on a substrate;
dry-etching the gate conductive layer and the gate insulating layer so that a sidewall of the gate insulating layer is recessed to beneath the gate conductive layer;
forming a buffer layer on the sidewall of the gate structure covering an interface in the gate structure between the gate conductive layer and the gate insulating layer; and
annealing the gate structure through the buffer layer to repair damage caused during the dry-etching.

19. A method of forming an integrated circuit device comprising:
forming a gate conductive layer on a gate insulating layer on a substrate;
dry-etching the gate conductive layer and the gate insulating layer so that a sidewall of the gate insulating layer is recessed to beneath the gate conductive layer;
forming a buffer layer on the sidewall of the gate structure covering an interface in the gate structure beneath the gate conductive layer between the gate conductive layer and the gate insulating layer; and
forming the buffer layer on the sidewall of the gate insulating layer beneath the gate conductive layer
annealing the gate structure through the buffer layer to repair damage caused during the dry-etching.
